(19) United States
(12) Patent Application Publication
(10) Pub. No.: US 2024/0352870 A1
(43) Pub. Date: Oct. 24, 2024

(54) METHOD FOR ESTIMATING FLANGE SURFACE PRESSURE DISTRIBUTION IN ROTARY MACHINE, METHOD FOR EVALUATING LEAKAGE OF FLUID FROM BETWEEN FLANGE SURFACES, AND PROGRAM AND DEVICE FOR EXECUTING THESE METHODS

(71) Applicant: MITSUBISHI HEAVY INDUSTRIES, LTD., Tokyo (JP)

(72) Inventors: Satoshi Kumagai, Tokyo (JP); Shunsuke Mizumi, Tokyo (JP); Koji Ishibashi, Tokyo (JP); Keisuke Uchino, Tokyo (JP)

(73) Assignee: MITSUBISHI HEAVY INDUSTRIES, LTD., Tokyo (JP)

(21) Appl. No.: 18/687,520

(22) PCT Filed: Nov. 30, 2022
(86) PCT No.: PCT/JP2022/044208

§ 371 Date: Feb. 28, 2024

(30) Foreign Application Priority Data
Feb. 25, 2022 (JP) 2022-027441

(51) Int. Cl. F01D 21/00; F01D 25/24; G01M 3/26

(52) U.S. Cl. CPC F01D 21/003; F01D 25/243; G01M 3/26; F05D 2260/31; F05D 2260/83

(57) ABSTRACT

A method for estimating a flange surface pressure distribution includes: a reference model receiving step of receiving a three-dimensional reference shape model of a rotary machine; a measured coordinate receiving step of receiving measured three-dimensional coordinate data at a plurality of positions on an upper flange surface and a lower flange surface when a casing is in an open state; a condition receiving step of receiving a tightening torque and an elastic coefficient of a plurality of bolts, elastic coefficients and weights of an upper-half casing and a lower-half casing, and the like; a modified model creating step of creating a three-dimensional modified shape model by modifying the three-dimensional reference shape model based on the measured three-dimensional coordinate data at the plurality of positions; and a pressure distribution estimating step of obtaining, by using the three-dimensional modified shape model and under the conditions received in the condition receiving step, a pressure distribution of a flange surface in a fastened state.

### TECHNICAL FIELD

The present disclosure relates to a method for estimating a flange surface pressure distribution that estimates a surface pressure distribution on flange surfaces of an upper-half casing and a lower-half casing covering an outer periphery of a rotor in a rotary machine, a method for evaluating leakage of a fluid from between the flange surfaces, and a program and a device for executing these methods.

This application claims priority based on JP 2022-027441 filed in Japan on Feb. 25, 2022, the contents of which are incorporated herein by reference.

### BACKGROUND ART

A rotary machine such as a steam turbine includes a rotor rotatable around an axis extending in a horizontal direction, a casing covering an outer periphery of the rotor, and a stationary component such as a diaphragm disposed in the casing and attached to the casing. The casing typically includes an upper-half casing on an upper side, a lower-half casing on a lower side, and a plurality of bolts fastening the upper-half casing to the lower-half casing. The upper-half casing includes an upper flange formed with an upper flange surface facing downward. The lower-half casing includes a lower flange formed with a lower flange surface facing upward and opposing the upper flange surface in the vertical direction.

At the time of inspection of the rotary machine, the upper-half casing is removed from the lower-half casing to put the rotary machine into an open state, and a plurality of components constituting the rotary machine are inspected and repaired as necessary. The casing of the rotary machine such as a steam turbine may have inelastic deformation such as creep deformation due to the influence of, for example, heat, during operation. For this reason, the lower-half casing and the upper-half casing in the open state after being operated once are deformed from the factory default in a strict sense. Upon completion of the inspection, the plurality of components are assembled. This assembly step includes a step of fastening the upper-half casing to the lower-half casing by using the plurality of bolts to bring them into a fastened state. In the course of bringing the lower-half casing and the upper-half casing from the open state to the fastened state, the lower-half casing and the upper-half casing are further deformed.

In such a rotary machine, sealing performance between an upper flange and a lower flange is important as described in Non-Patent Document 1 below. In Non-Patent Document 1, as a method for checking sealing performance, first, a paint is applied to one of check targets, and then the upper flange is fastened to the lower flange with bolts. Subsequently, the bolts are removed, and the paint adhesion state of the remaining one of the check targets is checked.

### CITATION LIST

### Non-Patent Literature

Non-Patent Document 1: “Valqua Technology News, No. 33 Summer 2017,” p. 10, edited and issued by NIPPON VALQUA INDUSTRIES, LTD. on Aug. 31, 2017

### SUMMARY OF INVENTION

### Technical Problem

In the technique described in Non-Patent Document 1 described above, in order to check the sealing performance between the upper flange and the lower flange, it is necessary to once fasten the upper flange to the lower flange with the bolts and then remove the bolts to return an upper-half casing and a lower-half casing to an open state. Thus, in the technique described in Non-Patent Document 1 described above, there is a problem in that it takes time and effort to check the sealing performance between the upper flange and the lower flange.

In light of the foregoing, an object of the present disclosure is to provide a technique that can reduce time and effort for checking sealing performance between two flanges.

### Solution to Problem

A method for estimating a flange surface pressure distribution in a rotary machine as one aspect for achieving the above-described object is applied to a rotary machine below.

The rotary machine includes: a rotor rotatable around an axis extending in a horizontal direction; a casing in which a working fluid flow and which covers an outer periphery of the rotor; and a stationary component disposed in the casing and attached to the casing. The casing includes an upper-half casing on an upper side, a lower-half casing on a lower side, and a plurality of bolts fastening the upper-half casing to the lower-half casing. The upper-half casing includes an upper flange formed with an upper flange surface facing downward. The lower-half casing includes a lower flange formed with a lower flange surface facing upward and opposing the upper flange surface in the vertical direction. The upper flange and the lower flange include bolt holes penetrating therethrough in the vertical direction, and the respective plurality of bolts can be inserted into the bolt holes.

The method for estimating a flange surface pressure distribution in the above rotary machine described above includes:
a reference model receiving step of receiving a three-dimensional reference shape model of the rotary machine, the three-dimensional reference shape model having been acquired in advance;
a measured coordinate receiving step of receiving measured three-dimensional coordinate data at a plurality of positions on the upper flange surface and measured three-dimensional coordinate data at a plurality of positions on the lower flange surface, the measured three-dimensional coordinate data being measured in an open state where the upper-half casing is not fastened to the lower-half casing by the plurality of bolts after the rotary machine is disassembled;
a condition receiving step of receiving conditions including a tightening torque of the plurality of bolts, an elastic coefficient of the plurality of bolts, elastic coefficients of the upper-half casing and the lower-half casing, weights of the upper-half casing and the lower-half casing, and a weight of the stationary component;
a modified model creating step of creating a three-dimensional modified shape model by modifying the three-dimensional reference shape model based on the measured coordinate data at the plurality of positions received in the measured coordinate receiving step; and
a pressure distribution estimating step of obtaining, by using the three-dimensional modified shape model and under the conditions received in the condition receiving step, a pressure distribution of one flange surface out of the lower flange surface and the upper flange surface when a state changes to a fastened state where the upper-half casing is fastened to the lower-half casing by the plurality of bolts.

In general, when the sealing performance between the upper flange and the lower flange is checked, a paint is first applied to one of check targets, and then the upper flange is fastened to the lower flange with bolts. Subsequently, the bolts are removed, the upper-half casing and the lower-half casing are returned to an open state, and then the paint adhesion state of the remaining one of the check targets is checked. However, in the present aspect, the pressure distribution of one flange surface out of the upper flange surface and the lower flange surface when the casing is changed to the fastened state is estimated. Accordingly, in the present aspect, in order to check the sealing performance between the upper flange and the lower flange, it is not necessary to bring the casing in the open state into the fastened state and then return the casing to the open state again, and thus it is possible to reduce the time and effort for checking the sealing performance.

A program for estimating a flange surface pressure distribution in a rotary machine as one aspect for achieving the above-described object is applied to a rotary machine below.

The rotary machine includes: a rotor rotatable around an axis extending in a horizontal direction; a casing in which a working fluid can flow and which covers an outer periphery of the rotor; and a stationary component disposed in the casing and attached to the casing. The casing includes an upper-half casing on an upper side, a lower-half casing on a lower side, and a plurality of bolts fastening the upper-half casing to the lower-half casing. The upper-half casing includes an upper flange formed with an upper flange surface facing downward. The lower-half casing includes a lower flange formed with a lower flange surface facing upward and opposing the upper flange surface in the vertical direction. The upper flange and the lower flange include bolt holes penetrating therethrough in the vertical direction, and the respective plurality of bolts can be inserted into the bolt holes.

The program for estimating a flange surface pressure distribution in the above rotary machine causes a computer to execute:
a reference model receiving step of receiving a three-dimensional reference shape model of the rotary machine, the three-dimensional reference shape model having been acquired in advance;
a measured coordinate receiving step of receiving measured three-dimensional coordinate data at a plurality of positions on the upper flange surface and measured three-dimensional coordinate data at a plurality of positions on the lower flange surface, the measured three-dimensional coordinate data being measured in an open state where the upper-half casing is not fastened to the lower-half casing by the plurality of bolts after the rotary machine is disassembled;
a condition receiving step of receiving conditions including a tightening torque of the plurality of bolts, an elastic coefficient of the plurality of bolts, elastic coefficients of the upper-half casing and the lower-half casing, weights of the upper-half casing and the lower-half casing, and a weight of the stationary component;
a modified model creating step of creating a three-dimensional modified shape model by modifying the three-dimensional reference shape model based on the measured coordinate data at the plurality of positions received in the measured coordinate receiving step; and
a pressure distribution estimating step of obtaining, by using the three-dimensional modified shape model and under the conditions received in the condition receiving step, a pressure distribution of one flange surface out of the lower flange surface and the upper flange surface when a state changes to a fastened state where the upper-half casing is fastened to the lower-half casing by the plurality of bolts.

By causing the computer to execute the program according to the present aspect, the time and effort for checking the sealing performance between the upper flange surface and the lower flange surface can be reduced as in the method according to the one aspect described above.

A device for estimating a flange surface pressure distribution in a rotary machine as one aspect for achieving the above-described object is applied to a rotary machine below.

The rotary machine includes: a rotor rotatable around an axis extending in a horizontal direction; a casing in which a working fluid can flow and which covers an outer periphery of the rotor; and a stationary component disposed in the casing and attached to the casing. The casing includes an upper-half casing on an upper side, a lower-half casing on a lower side, and a plurality of bolts fastening the upper-half casing to the lower-half casing. The upper-half casing includes an upper flange formed with an upper flange surface facing downward. The lower-half casing includes a lower flange formed with a lower flange surface facing upward and opposing the upper flange surface in the vertical direction. The upper flange and the lower flange include bolt holes penetrating therethrough in the vertical direction, and the respective plurality of bolts can be inserted into the bolt holes.

The device for estimating a flange surface pressure distribution in the above rotary machine includes:
a reference model receiving unit configured to receive a three-dimensional reference shape model of the rotary machine, the three-dimensional reference shape model having been acquired in advance;
a measured coordinate receiving unit configured to receive measured three-dimensional coordinate data at a plurality of positions on the upper flange surface and measured three-dimensional coordinate data at a plurality of positions on the lower flange surface, the measured three-dimensional coordinate data being measured in an open state where the upper-half casing is not fastened to the lower-half casing by the plurality of bolts after the rotary machine is disassembled;
a condition receiving unit configured to receive conditions including a tightening torque of the plurality of bolts, an elastic coefficient of the plurality of bolts, elastic coefficients of the upper-half casing and the lower-half casing, weights of the upper-half casing and the lower-half casing, and a weight of the stationary component;
a modified model creating unit configured to create a three-dimensional modified shape model by modifying the three-dimensional reference shape model based on the measured coordinate data at the plurality of positions received by the measured coordinate receiving unit; and
a pressure distribution estimating unit configured to obtain, by using the three-dimensional modified shape model and under the conditions received by the condition receiving unit, a pressure distribution of one flange surface out of the lower flange surface and the upper flange surface when a state changes to a fastened state where the upper-half casing is fastened to the lower-half casing by the plurality of bolts.

Similar to the method according to the one aspect described above, in the present aspect, the time and effort for checking the sealing performance between the upper flange surface and the lower flange surface can be reduced.

### Advantageous Effects of Invention

According to one aspect of the present disclosure, a flange surface pressure distribution in a rotary machine can be estimated, and thus the time and effort for checking the sealing performance between the two flanges can be reduced.

### BRIEF DESCRIPTION OF DRAWINGS

FIG. 1 is a schematic diagram illustrating a schematic configuration of a steam turbine that is a rotary machine according to an embodiment of the present disclosure.

FIG. 2 is a schematic diagram illustrating an outline of a steam turbine that is a rotary machine in the embodiment according to the present disclosure.

FIG. 3 is a plan view illustrating a main part of an upper-half casing and a main part of a lower-half casing in the embodiment according to the present disclosure.

FIG. 4 is a cross-sectional view illustrating a casing in an open state in the embodiment according to the present disclosure.

FIG. 5 is a cross-sectional view illustrating the casing in a fastened state in the embodiment according to the present disclosure.

FIG. 6 is a functional block diagram of a device for evaluating leakage in the embodiment according to the present disclosure.

FIG. 7 is a flowchart illustrating a procedure for performing a method for evaluating leakage in the embodiment according to the present disclosure.

FIG. 8 is an explanatory diagram illustrating positions on a flange surface at which measured three-dimensional coordinate data is acquired in the embodiment according to the present disclosure.

FIG. 9 is an image diagram illustrating a relative positional relationship between a three-dimensional reference shape model and points indicated by measured three-dimensional coordinate data at a plurality of positions on an actual flange surface in the embodiment according to the present disclosure.

FIG. 10 is an explanatory diagram for describing a plurality of pieces of polygon data in the embodiment according to the present disclosure.

FIG. 11 is an explanatory diagram for describing extraction of a plurality of pieces of specific polygon data from the plurality of pieces of polygon data in the embodiment according to the present disclosure.

FIG. 12 is an image diagram illustrating a relative positional relationship between the three-dimensional reference shape model and points extracted from the points indicated by the measured three-dimensional coordinate data at the plurality of positions on the actual flange surface by polygon data extraction processing in the embodiment according to the present disclosure.

FIG. 13 is an explanatory diagram illustrating a process of obtaining surface shape data of a flange surface by using the measured three-dimensional coordinate data at the plurality of positions on the actual flange surface in the embodiment according to the present disclosure.

FIG. 14 is an explanatory diagram illustrating a procedure for creating a three-dimensional modified shape model in the embodiment according to the present disclosure.

FIG. 15 is an explanatory diagram illustrating a surface pressure distribution on a flange surface in the embodiment according to the present disclosure.

FIG. 16 is an explanatory diagram illustrating high leakage regions on a flange surface in the embodiment according to the present disclosure.

FIG. 17 is an explanatory diagram illustrating a creep model in the embodiment according to the present disclosure.

### DESCRIPTION OF EMBODIMENTS

Embodiments of a method for estimating a flange surface pressure distribution in a rotary machine, a method for evaluating leakage of a fluid from between flange surfaces, a program for executing these methods, and a device for executing these methods according to the present disclosure will be described below.

### Embodiment of Rotary Machine

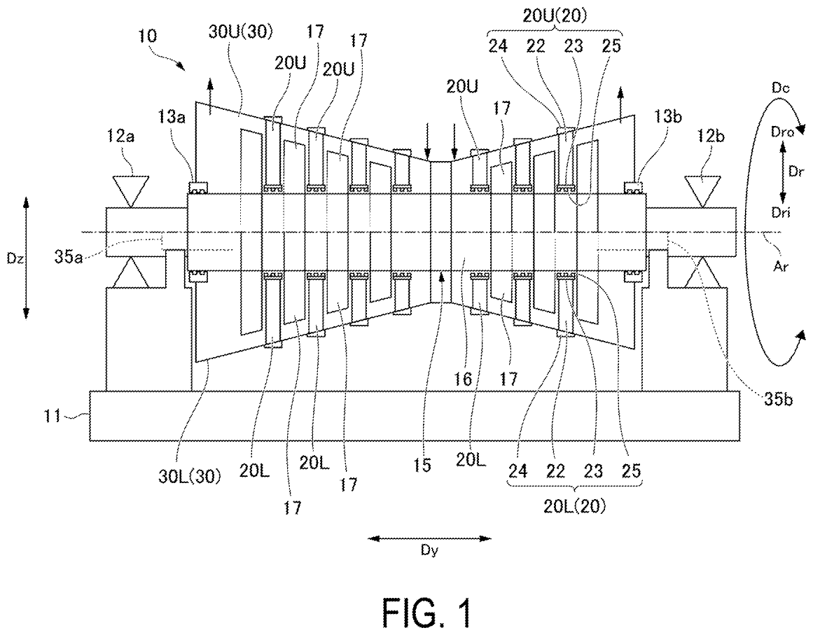

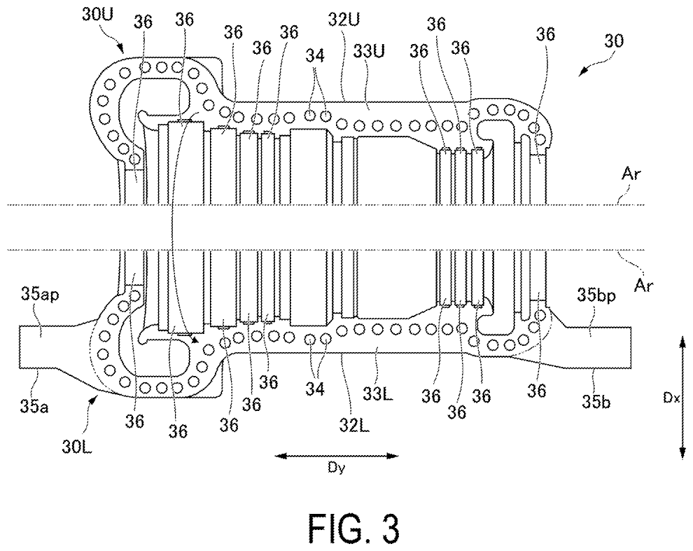

A rotary machine in the present embodiment will be described with reference to FIGS. 1 to 5.

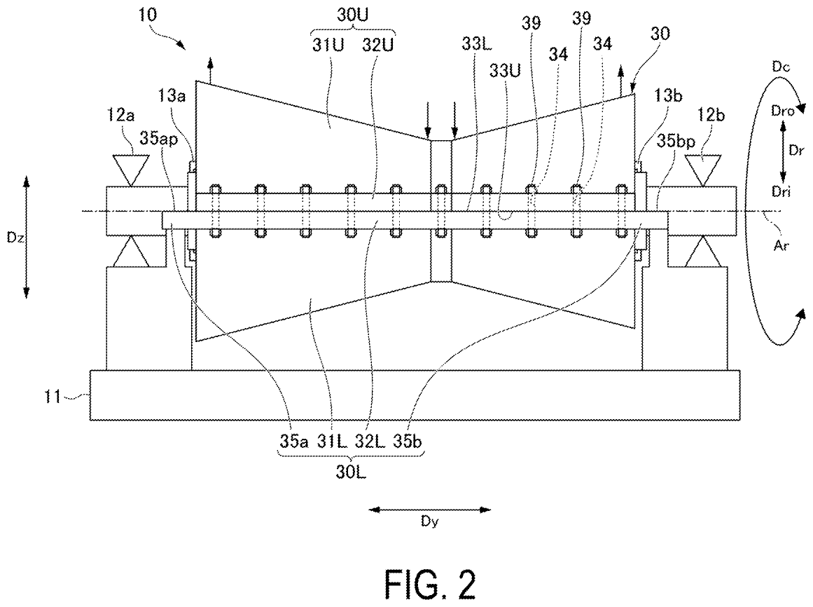

As illustrated in FIGS. 1 and 2, the rotary machine in the present embodiment is a steam turbine 10. The steam turbine 10 includes a rotor 15 that rotates around an axis Ar extending in the horizontal direction, a casing 30 that covers an outer periphery side of the rotor 15, a first shaft bearing device 12a and a second shaft bearing device 12b that rotatably support the rotor 15, a plurality of diaphragms 20, a first shaft sealing device 13a and a second shaft sealing device 13b that seal gaps between the casing 30 and the rotor 15, and a frame 11 that supports the casing 30 from below.

Here, a direction in which the axis Ar extends is referred to as an axial direction Dy, a circumferential direction with respect to the axis Ar is simply referred to as a circumferential direction Dc, and a radial direction with respect to the axis Ar is simply referred to as a radial direction Dr. Further, in the radial direction Dr, a side closer to the axis Ar is referred to as a radial inner side Dri, and a side far from the axis Ar is referred to as a radial outer side Dro. In addition, among the reference signs used in the drawings, U means an upper half and L means a lower half.

The rotor 15 includes a rotor shaft 16 extending in the axial direction Dy, and a plurality of rotor blade rows 17 attached to the rotor shaft 16 along the axial direction Dy. Each of the plurality of rotor blade rows 17 includes a plurality of rotor blades aligned in the circumferential direction Dc with respect to the axis Ar. Both end portions of the rotor shaft 16 protrude from the casing 30 in the axial direction Dy. One end portion of the rotor shaft 16 in the axial direction Dy is rotatably supported by the first shaft bearing device 12a mounted on the frame 11. The other end portion of the rotor shaft 16 in the axial direction Dy is rotatably supported by the second shaft bearing device 12b mounted on the frame 11.

The first shaft sealing device 13a is provided at one end portion of the casing 30 in the axial direction Dy. The second shaft sealing device 13b is provided at the other end portion of the casing 30 in the axial direction Dy. Each of the first shaft sealing device 13a and the second shaft sealing device 13b is a device that seals a gap between the rotor shaft 16 and the casing 30.

The plurality of diaphragms 20 are aligned in the axial direction Dy in the casing 30. Each of the plurality of diaphragms 20 includes a lower-half diaphragm 20L that constitutes a portion below the axis Ar and an upper-half diaphragm 20U that constitutes a portion above the axis Ar. Each of the lower-half diaphragm 20L and the upper-half diaphragm 20U includes a plurality of stator vanes 22 aligned in the circumferential direction Dc, a diaphragm inner ring 23 that connects portions of the plurality of stator vanes 22 on the radial inner side Dri to each other, a diaphragm outer ring 24 that connects portions of the plurality of stator vanes 22 on the radial outer side Dro to each other, and a sealing device 25 mounted on the radial inner side Dri of the diaphragm inner ring 23. The sealing device 25 is a sealing device that seals a gap between the diaphragm inner ring 23 and the rotor shaft 16.

Each of the first shaft sealing device 13a, the second shaft sealing device 13b, and the plurality of diaphragms 20 described above is a stationary component that extends in the circumferential direction with respect to the axis Ar and is attached to the casing 30.

As illustrated in FIG. 2, the casing 30 includes a lower-half casing 30L that constitutes a portion below the axis Ar, an upper-half casing 30U that constitutes a portion above the axis Ar, and a plurality of bolts 39 for fastening the upper-half casing 30U to the lower-half casing 30L. The lower-half casing 30L includes a lower-half casing main body 31L extending in the circumferential direction Dc, a lower flange 32L protruding from both end portions of the lower-half casing main body 31L in the circumferential direction Dc toward the radial outer side Dro, and a first supported portion 35a and a second supported portion 35b that are continuous with the lower flange 32L and are supported by the frame 11 from below. The upper-half casing 30U includes an upper-half casing main body 31U extending in the circumferential direction Dc and an upper flange 32U protruding from both end portions of the upper-half casing main body 31U in the circumferential direction Dc toward the radial outer side Dro.

As illustrated in FIGS. 2 to 5, a surface of the lower flange 32L facing upward constitutes a lower flange surface 33L. A surface of the upper flange 32U facing downward constitutes an upper flange surface 33U. The lower flange surface 33L and the upper flange surface 33U face each other in a vertical direction Dz.

The first supported portion 35a protrudes from one side of both sides of the lower flange 32L in the axial direction Dy toward the one side. The second supported portion 35b protrudes from the other side of the both sides of the lower flange 32L in the axial direction Dy toward the other side. Thus, the second supported portion 35a is separated from the first supported portion 35b in the axial direction Dy. In the present embodiment, an upper surface 35ap of the first supported portion 35a and an upper surface 35bp of the second supported portion 35b are surfaces continuous with the lower flange surface 33L.

The lower flange 32L and the upper flange 32U are formed with bolt holes 34 which penetrate therethrough in the vertical direction Dz, and the respective plurality of bolts 39 can be inserted into the bolt holes 34. The lower-half casing 30L and the upper-half casing 30U are fastened by the bolts 39 inserted into the bolt holes 34 of the lower flange 32L and the bolt holes 34 of the upper flange 32U.

An inside surface of the lower-half casing main body 31L and an inside surface of the upper-half casing 30U are formed with stationary component storage portions 36 in which the respective plurality of stationary components described above is stored. Each of the stationary component storage portions 36 of the lower-half casing main body 31L is a groove that is recessed from the inside surface of the lower-half casing main body 31L toward the radial outer side Dro and extends in the circumferential direction Dc. Each of the stationary component storage portions 36 of the upper-half casing main body 31U is a groove that is recessed from the inside surface of the upper-half casing main body 31U toward the radial outer side Dro and extends in the circumferential direction Dc. The diaphragm 20, which is one of the stationary components, is supported by a portion near the flange surface of the stationary component storage portion 36 extending in the circumferential direction Dc.

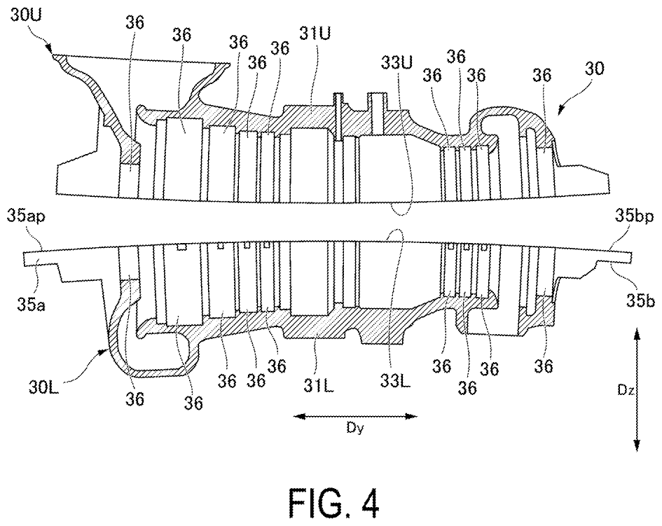

An inside surface of the casing 30 is exposed to high-temperature steam generated by the operation of the steam turbine 10. Thus, the casing 30 may undergo inelastic deformation such as creep deformation due to the operation of the steam turbine 10. As a result of this deformation, in the open state where the upper-half casing 30U is not fastened to the lower-half casing 30L, the positions of the lower flange surface 33L and the upper flange surface 33U in the vertical direction Dz are shifted according to a location in the axial direction Dy as illustrated in FIG. 4.

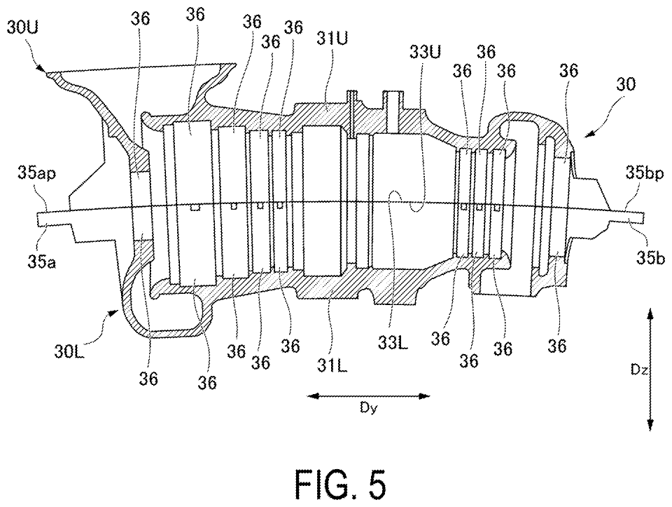

When the upper-half casing 30U deformed as described above is fastened to the lower-half casing 30L deformed as described above to bring the casing 30 into the fastened state, the positions of the lower flange surface 33L and the upper flange surface 33U in the vertical direction Dz are further shifted according to a location in the axial direction Dy as illustrated in FIG. 5. That is, when the casing is changed from the open state to the fastened state, the upper flange surface 33U and the lower flange surface 33L are deformed.

In the steam turbine 10, the sealing performance between the upper flange surface 33U and the lower flange surface 33L is important for suppressing leakage of steam from between the upper flange surface 33U and the lower flange surface 33L. As described above, the casing is deformed when a state changes from the open state to the fastened state. Thus, even when the shapes of the upper flange surface and the lower flange surface in the open state are known in advance, it is not possible to grasp the sealing performance between the upper flange surface 33U and the lower flange surface 33L directly from these surface shapes.

Therefore, embodiments of a device for estimating a flange surface pressure distribution that estimates the surface distribution on the flange surface in the steam turbine 10 which is a rotary machine, a method for evaluating leakage of a fluid from between flange surfaces, a program for executing these methods, and a device for executing these methods will be described.

### Embodiment of Device for Estimating a Flange Surface Pressure Distribution and Device for Evaluating Leakage

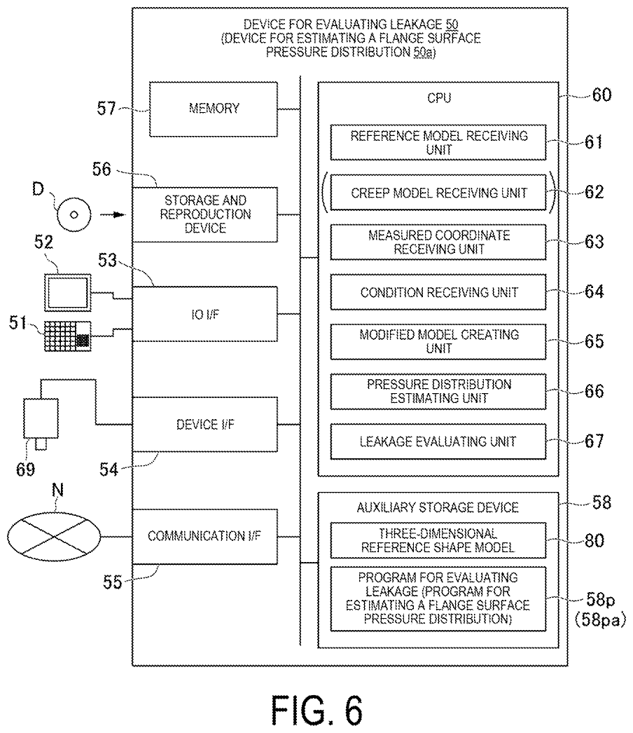

A device for estimating a flange surface pressure distribution and a device for evaluating leakage according to the present embodiment will be described with reference to FIG. 6.

A device for evaluating leakage 50 according to the present embodiment includes a device for estimating a flange surface pressure distribution 50a. The device for evaluating leakage 50 is a computer. The device for evaluating leakage 50 includes a central processing unit (CPU) 60 that performs various operations, a memory 57 that serves as a working area or the like for the CPU 60, an auxiliary storage device 58 such as a hard disk drive device, a manual input device (input device) 51 such as a keyboard and a mouse, a display device (output device) 52, an input/output interface 53 for the manual input device 51 and the display device 52, a device interface (input device) 54 for transmitting and receiving data to and from a three-dimensional shape measuring device 69 such as a three-dimensional laser measuring device, a communication interface (input/output device) 55 for communicating with the outside via a network N, and a storage and reproduction device (input/output device) 56 that performs data storage processing and data reproduction processing for a disk storage medium D which is a non-transitory storage medium.

The auxiliary storage device 58 stores in advance a program for evaluating leakage 58p. The program for evaluating leakage 58p includes a program for estimating a flange surface pressure distribution 58pa. The program for evaluating leakage 58p is loaded into the auxiliary storage device 58 from the disk storage medium D, which is a non-transitory storage medium, via the storage and reproduction device 56, for example. Note that the program for evaluating leakage 58p may be loaded into the auxiliary storage device 58 from an external device via the communication interface 55.

The CPU 60 functionally includes a reference model receiving unit 61, a measured coordinate receiving unit 63, a condition receiving unit 64, a modified model creating unit 65, a pressure distribution estimating unit 66, and a leakage evaluating unit 67. Each of these functional units 61 and 63 to 67 is enabled by the CPU 60 executing the program for evaluating leakage 58p stored in the auxiliary storage device 58. Among the functional units 61 and 63 to 67 described above, the functional units 61 and 63 to 66 excluding the leakage evaluating unit 67 are enabled by the CPU 60 executing the program for estimating a flange surface pressure distribution 58pa included in the program for evaluating leakage 58p. The device for estimating a flange surface pressure distribution 50a included in the device for evaluating leakage 50 includes the functional units 61 and 63 to 66 excluding the leakage evaluating unit 67 among the functional units 61 and 63 to 67 described above. The operations of the respective functional units 61 and 63 to 67 will be described below.

### First Embodiment of Method for Estimating a Flange Surface Pressure Distribution in a Rotary Machine and Method for Evaluating Leakage of a Fluid From Between Flange Surfaces

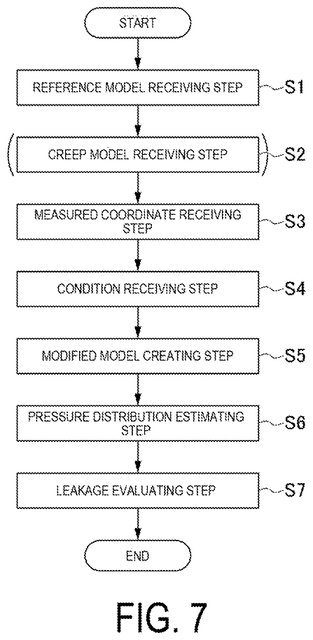

The method for estimating a flange surface pressure distribution and the method for evaluating leakage of a fluid from between flange surfaces according to the present embodiment will be described in accordance with a flowchart illustrated in FIG. 7. Note that the method for estimating a flange surface pressure distribution and the method for evaluating leakage of a fluid from between flange surfaces are executed by the device for evaluating leakage 50 described above.

An operator inputs a three-dimensional reference shape model 80 of the steam turbine 10 acquired in advance to the device for evaluating leakage 50. The input method may be any one of input by the manual input device 51, input via the network N from a computer in which the three-dimensional reference shape model 80 is stored, and input via the storage and reproduction device 56 from the disk storage medium D in which the three-dimensional reference shape model 80 is stored. As described above, the reference model receiving unit 61 of the device for evaluating leakage 50 receives the input of the three-dimensional reference shape model 80 from the outside and stores the three-dimensional reference shape model 80 in the auxiliary storage device 58 (reference model receiving step S1).

The three-dimensional reference shape model 80 is a model in which a plurality of components constituting the steam turbine 10 are divided into a plurality of minute elements in the form of a mesh in order to simulate deformation or the like of the plurality of components by a finite element method or the like. The three-dimensional reference shape model 80 may be a model represented by three-dimensional design data created at the time of designing the steam turbine 10, or may be a model represented by three-dimensional data obtained by actual measurement performed, for example, before the shipment of the steam turbine 10 from a factory, or at the time of a previous periodic inspection. That is, the three-dimensional reference shape model 80 only needs to be a model represented by three-dimensional data obtained ahead of operation before a periodic inspection. Three-dimensional coordinate data at respective positions of the plurality of components constituting the steam turbine 10 can be obtained from the three-dimensional reference shape model 80.

The steam turbine 10 is disassembled and reassembled each time an inspection or the like is performed. When the disassembly of the steam turbine 10 is completed, the upper-half casing 30U is removed from the lower-half casing 30L as illustrated in FIG. 4. As a result, the casing 30 is in the open state where the upper-half casing 30U and the lower-half casing 30L are not fastened by the bolts 39. Further, the rotor 15, the plurality of diaphragms 20, the first shaft sealing device 13a, and the second shaft sealing device 13b are removed from the casing 30 and placed outside the casing 30. The lower-half casing 30L may be removed from the frame 11 when the disassembly of the steam turbine 10 is completed, but here, it is assumed that the lower-half casing 30L is supported by the frame 11.

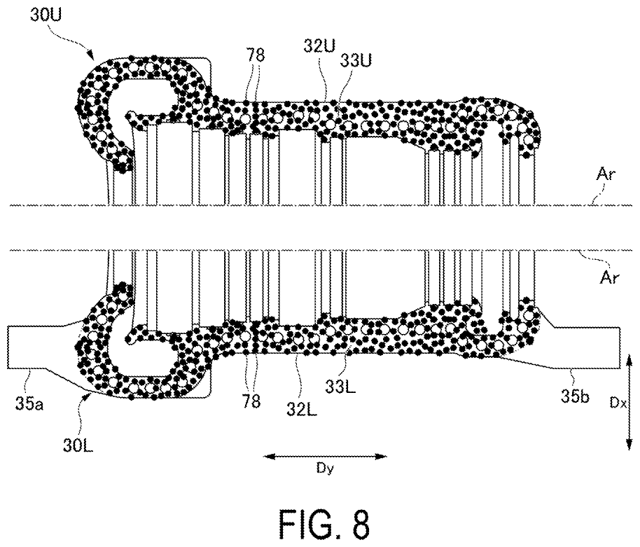

When the steam turbine 10 is disassembled and the casing 30 is in the open state as described above, the operator measures three-dimensional coordinate values at a plurality of positions 78 on the upper flange surface 33U and three-dimensional coordinate values at a plurality of positions 78 on the lower flange surface 33L by using the three-dimensional shape measuring device 69 such as a three-dimensional laser measuring device as illustrated in FIG. 8. At this time, it is desirable to secure a sufficient number of measurement points for accurately reproducing the detailed shapes of the upper flange surface 33U and the lower flange surface 33L. Then, the operator causes the three-dimensional shape measuring device 69 to transfer, as measured three-dimensional coordinate data, the three-dimensional coordinate values at the plurality of positions 78 on the upper flange surface 33U and the three-dimensional coordinate values at the plurality of positions 78 on the lower flange surface 33L to the device for evaluating leakage 50. The measured coordinate receiving unit 63 of the device for evaluating leakage 50 receives the measured three-dimensional coordinate data at the plurality of positions 78 on the upper flange surface 33U and the measured three-dimensional coordinate data at the plurality of positions 78 on the lower flange surface 33L (measured coordinate receiving step S3).

The three-dimensional coordinate data according to the present embodiment includes a coordinate value indicating a position in the axial direction Dy extending in the horizontal direction, a coordinate value indicating a position in the vertical direction Dz perpendicular to the axial direction Dy, and a coordinate value indicating a position in a lateral direction Dx perpendicular to the axial direction Dy in the horizontal direction.

The operator further inputs conditions for evaluating leakage of steam by using the manual input device 51 or the like. The condition receiving unit 64 of the device for evaluating leakage 50 receives the conditions (condition receiving step S4). The conditions include a tightening torque of the plurality of bolts 39, an elastic coefficient of the plurality of bolts 39, elastic coefficients of the upper-half casing 30U and the lower-half casing 30L, weights of the upper-half casing 30U and the lower-half casing 30L, a weight of the stationary component, and the like.

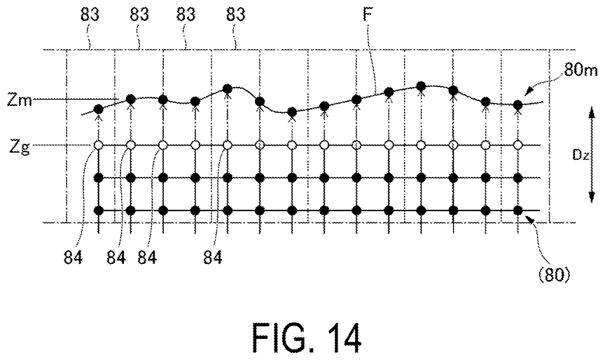

When the measured coordinate receiving unit 63 receives a plurality of pieces of measured three-dimensional coordinate data and the condition receiving unit 64 receives the conditions, the modified model creating unit 65 of the device for evaluating leakage 50 modifies the three-dimensional reference shape model 80 based on the measured three-dimensional coordinate data at the plurality of positions 78 received by the measured coordinate receiving unit 63 to create a three-dimensional modified shape model 80m (see FIG. 14) (modified model creating step S5).

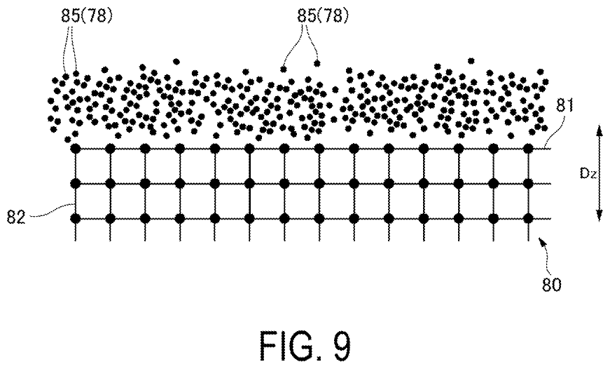

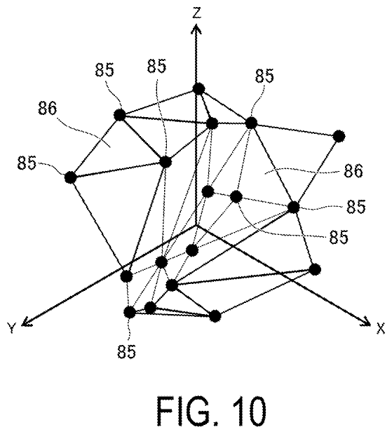

For example, as illustrated in FIG. 9, points 85 indicated by the plurality of pieces of measured three-dimensional coordinate data are present with variations within a certain range of accuracy with respect to a flange surface 81 of the three-dimensional reference shape model 80. First, the modified model creating unit 65 creates a plurality of pieces of polygon data using the plurality of measured three-dimensional coordinate data. The polygon data is data that defines a polygon plane. As illustrated in FIG. 10, the modified model creating unit 65 connects, among the plurality of points 85 indicated by the measured three-dimensional coordinate data at the plurality of positions, a plurality of points 85 adjacent to each other with line segments. A polygonal plane surrounded by these line segments is referred to as a polygon 86.

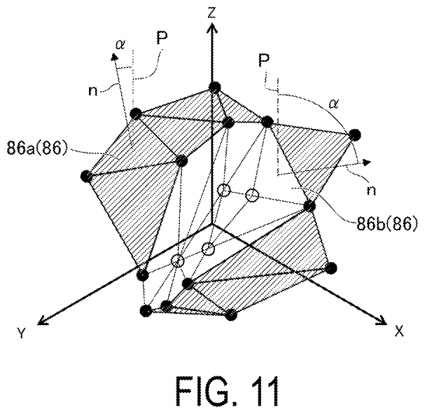

Subsequently, as illustrated in FIG. 11, the modified model creating unit 65 extracts, from among the plurality of pieces of polygon data, a plurality of pieces of polygon data that satisfy a certain condition. In FIG. 11, polygons 86a identified by the polygon data to be extracted are patterned, and polygons 86b identified by the polygon data not to be extracted are not patterned. In addition, an XY plane in FIG. 11 is a plane parallel to the flange surface 81 of the three-dimensional reference shape model 80. Here, the condition described above is that an inclination of the polygon 86 identified by the polygon data with respect to the flange surface 81 of the three-dimensional reference shape model 80 is within a predetermined inclination. The modified model creating unit 65 first obtains a normal line n of the polygon 86 for each of the plurality of polygons 86. Next, the modified model creating unit 65 obtains an angle α between a perpendicular line p to the flange surface 81 of the three-dimensional reference shape model 80 and the normal line n of the polygon 86 for each of the plurality of polygons 86. Then, the modified model creating unit 65 extracts, from among the plurality of pieces of polygon data, a plurality of pieces of polygon data in which the angle α between the perpendicular line p to the flange surface 81 and the normal line n of the polygon 86 is within a predetermined angle (predetermined inclination).

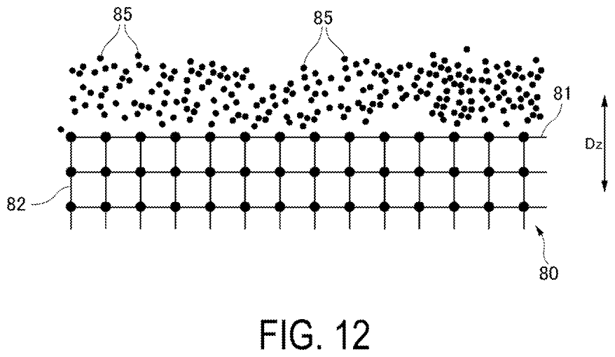

This data extraction processing is performed to exclude, from the measured three-dimensional coordinate data at the plurality of points 85 received in the measured coordinate receiving step S3, measured three-dimensional coordinate data at points on a wall of an edge of the flange surface and points on the inside surfaces of the bolt holes 34 penetrating through the flange surface. Thus, as illustrated in FIG. 12, the number of the points 85 after the extraction processing is less than the number of the points 85 before the extraction processing. In particular, the number of the points 85 after the extraction processing is significantly less than the number of the points 85 before the extraction processing for a surface 82 that is inclined with respect to the flange surface 81 in the three-dimensional reference shape model 80.

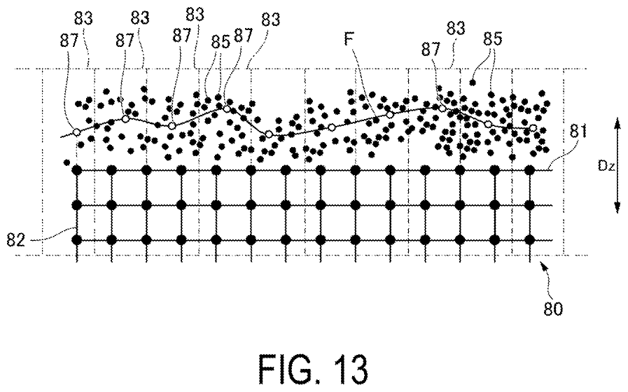

Next, as illustrated in FIG. 13, the modified model creating unit 65 divides a virtual three-dimensional space including the flange surface 81 into a plurality of three-dimensional blocks 83. Then, the modified model creating unit 65 sets a representative point 87 in a target three-dimensional block 83 for each of the plurality of three-dimensional blocks 83. Specifically, the modified model creating unit 65 selects, from among the plurality of points 85 included in the polygons 86a identified by the plurality of pieces of polygon data extracted in the extraction processing, a point that is a median of the plurality of points 85 included in the target three-dimensional block 83 as the representative point 87 in the target three-dimensional block 83.

The measured three-dimensional coordinate data related to the point 85 obtained by the three-dimensional shape measuring device 69 contains an error. For example, when the three-dimensional shape measuring device 69 is a three-dimensional laser measuring device, the measured three-dimensional coordinate data measured by the three-dimensional laser measuring device will contain an error when there is a minute floating object between a measurement target and the three-dimensional laser measuring device. Thus, in the present embodiment, an error range of the three-dimensional coordinate data related to the point 85 obtained by the three-dimensional shape measuring device 69 is narrowed by setting a point that is the median of the plurality of points 85 included in the three-dimensional block 83 as the representative point 87 in the three-dimensional block 83. Note that when the number of the plurality of points 85 included in the three-dimensional block 83 is extremely small, the representative point 87 is not set for this three-dimensional block 83. This is because when the number of the points 85 is extremely small, even when the representative point 87 is set among the plurality of points 85, the error range of the three-dimensional coordinate data of the representative point 87 is not necessarily narrowed.

The representative point 87 may be determined by robust estimation or bi-weight estimation based on the Lorentz distribution of the plurality of points 85 included in the polygons 86a identified by the plurality of pieces of polygon data extracted in the extraction processing.

The modified model creating unit 65 connects the respective representative points 87 of the plurality of three-dimensional blocks 83 to each other with a plane or a curved surface as a complementary surface to create surface shape data of the complementary surface including the respective representative points 87 of the plurality of three-dimensional blocks 83. The surface shape data is represented by a function F indicating the shape of the entire flange surface.

As illustrated in FIG. 14, the modified model creating unit 65 modifies the three-dimensional reference shape model 80 by using the function F to create the three-dimensional modified shape model 80m. Specifically, among a coordinate value xg indicating a position in the lateral direction Dx, a coordinate value yg indicating a position in the axial direction Dy, and a coordinate value zg indicating a position in the vertical direction Dz related to each of grids 84 included in the flange surface 81 in the three-dimensional reference shape model 80, the coordinate value zg is converted by the modified model creating unit 65 into a coordinate value zm that corresponds to the coordinate values xg and yg obtained by the function F. As described above, the modified model creating unit 65 sets a model obtained by changing the coordinate value zg related to each of the grids 84 included in the flange surface 81 of the three-dimensional reference shape model 80 as the three-dimensional modified shape model 80m. Then, the modified model creating step S5 is ended.

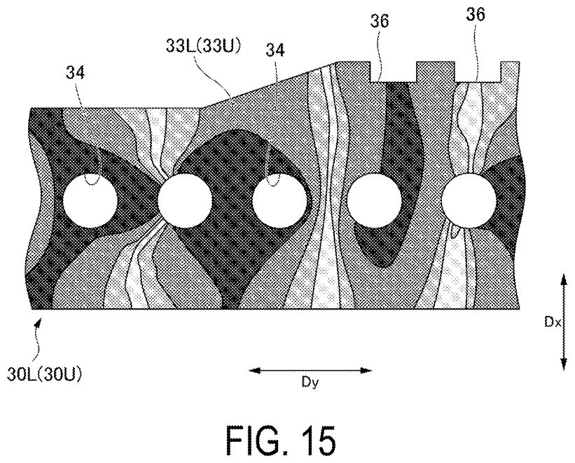

When the three-dimensional modified shape model 80m is created, the pressure distribution estimating unit 66 simulates the distribution of pressure applied to one flange surface out of the upper flange surface 33U and the lower flange surface 33L under the conditions received in the condition receiving step S4 by using the three-dimensional modified shape model 80m (pressure distribution estimating step S6). First, for all meshes including surfaces that form the flange surface (hereinafter referred to as mesh flange surfaces) among a plurality of meshes in the three-dimensional modified shape model 80m, the pressure distribution estimating unit 66 obtains pressures applied to the mesh flange surfaces by simulation. Next, the pressure distribution estimating unit 66 sets a region in which mesh flange surfaces within a predetermined pressure range are present as a region to which a pressure within the predetermined pressure range is applied in the flange surface. For example, as illustrated in FIG. 15, the pressure distribution estimating unit 66 displays the distribution of the pressure applied to the flange surface on the display device 52.

The above-described operations in the device for evaluating leakage 50 are operations by the device for estimating a flange surface pressure distribution 50a included in the device for evaluating leakage 50.

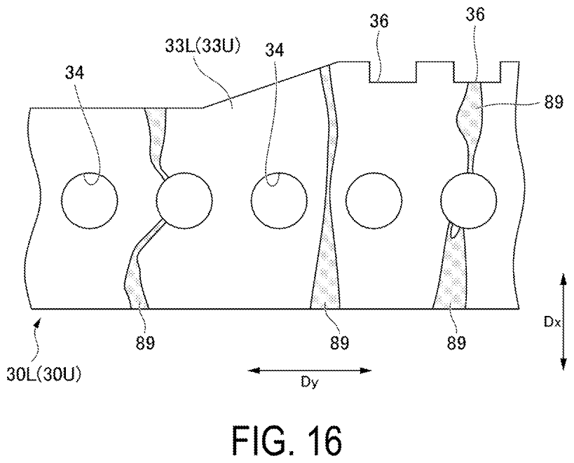

When the distribution of the pressure applied to the flange surface is obtained, the leakage evaluating unit 67 of the device for evaluating leakage 50 obtains a high leakage region in which steam is highly likely to leak in the flange surface (leakage evaluating step S7). Here, the leakage evaluating unit 67 obtains a region in which a value obtained by dividing the pressure indicated by the pressure distribution obtained in advance by the maximum pressure or the rated pressure of the steam (working fluid) is less than a predetermined tolerance, and sets this region as the high leakage region. For example, as illustrated in FIG. 16, the leakage evaluating unit 67 displays high leakage regions 89 in the flange surface on the display device 52.

If the high leakage region 89 is present in the flange surface, the operator sets a tightening torque of the bolt 39 inserted into the bolt hole 34 close to the high leakage region 89 to be high. At this time, if necessary, the operator changes the material of the bolt 39 so that the bolt 39 can withstand the set tightening torque.

As described in the background art section, when the sealing performance between the upper flange 32U and the lower flange 32L is checked, a paint is first applied to one of check targets, and then the upper flange 32U is fastened to the lower flange 32L with bolts 39. Subsequently, the bolts 39 are removed, the upper-half casing 30U and the lower-half casing 30L are returned to the open state, and then the paint adhesion state of the remaining one of the check targets is checked. However, in the present embodiment, the distribution of pressure applied to one flange surface out of the upper flange surface 33U and the lower flange surface 33L when the casing 30 is changed to the fastened state is estimated by simulation. Accordingly, in the present embodiment, in order to check the sealing performance between the upper flange 32U and the lower flange 32L, it is not necessary to bring the casing 30 in the open state into the fastened state and then return the casing 30 to the open state again, and thus it is possible to reduce the time and effort for checking the sealing performance.

Further, in the present embodiment, since the high leakage region 89 is estimated in the flange surface, the sealing performance can be easily checked.

In the present embodiment, the distribution of pressure applied to the flange surface and the high leakage region 89 are displayed on the display device 52. However, when the high leakage region 89 is displayed on the display device 52, the distribution of pressure applied to the flange surface need not be displayed on the display device 52.

In the present embodiment, the distribution of pressure applied to the flange surface and the high leakage region 89 are estimated. However, the distribution of pressure applied to the flange surface is estimated while the high leakage region 89 need not be estimated.

In the present embodiment, after the reference model receiving step SI, the measured coordinate receiving step S3 is executed, and then the condition receiving step S4 is executed. However, the reference model receiving step SI and the measured coordinate receiving step S3 may be executed in any order as long as these steps are executed before the modified model creating step S5. In addition, the condition receiving step S4 may be executed in any order as long as this step is executed before the pressure distribution estimating step S6.

### Second Embodiment of Method for Estimating a Flange Surface Pressure Distribution in a Rotary Machine and Method for Evaluating Leakage of a Fluid From Between Flange Surfaces

In the first embodiment, the distribution of pressure applied to the flange surface and the high leakage region 89 when the casing 30 is in the fastened state are estimated. On the other hand, in the present embodiment, the distribution of pressure applied to the flange surface and the high leakage region 89 when the casing 30 is in the fastened state and the steam turbine 10 is in operation are estimated.

A device for executing the method according to the present embodiment is the same as the device 50 described with reference to FIG. 6. In addition, a procedure for executing the method is the same as the execution procedure described in the flowchart illustrated in FIG. 7. However, in the present embodiment, conditions received in the condition receiving step S4 are different from the conditions received in the condition receiving step S4 in the first embodiment.

In the condition receiving step S4 in the present embodiment, in addition to the conditions received in the condition receiving step S4 in the first embodiment, the condition receiving unit 64 receives, as conditions, a pressure distribution and a temperature distribution in the casing 30, a temperature outside the casing 30, a thrust force applied to the stationary component, a linear expansion coefficient of the bolt 39 according to temperature, and linear expansion coefficients and heat transfer coefficients of the upper-half casing 30U and the lower-half casing 30L according to temperature when the steam turbine 10 is in operation.

In the pressure distribution estimating step S6 in the present embodiment, the pressure distribution estimating unit 66 simulates the distribution of pressure applied to the flange surface when the casing 30 is in the fastened state and the steam turbine 10 is in operation by using the conditions received in the condition receiving step S4.

Also in the leakage evaluating step S7 in the present embodiment, the leakage evaluating unit 67 obtains the high leakage region 89 in which steam is highly likely to leak in the flange surface.

In the present embodiment, the pressure distribution of the flange surface when the casing 30 is in the fastened state and the steam turbine 10 is in operation is estimated by simulation. Accordingly, in the present embodiment, the sealing performance when the steam turbine 10 is in operation can be checked.

Note that in order to increase the accuracy of simulating the pressure distribution, a heat transfer coefficient between the steam and the casing 30 according to the temperature of the upper-half casing 30U and the lower-half casing 30L may be further received in the condition receiving step S4 according to the present embodiment.

### Third Embodiment of Method for Estimating a Flange Surface Pressure Distribution in a Rotary Machine and Method for Evaluating Leakage of a Fluid From Between Flange Surfaces

In the first embodiment, the distribution of pressure applied to the flange surface and the high leakage region 89 when the casing 30 is in the fastened state are estimated. On the other hand, the present embodiment estimates the distribution of pressure applied to the flange surface and the high leakage region 89 when the casing 30 is in the fastened state and the steam turbine 10 is in operation, and after a flow rate of steam is changed.

A device for executing the method according to the present embodiment is the same as the device 50 described with reference to FIG. 6. In addition, a procedure for executing the method is the same as the execution procedure described in the flowchart illustrated in FIG. 7. However, in the present embodiment, conditions received in the condition receiving step S4 are different from the conditions received in the condition receiving step S4 in the first embodiment.

Similar to the condition receiving step S4 in the second embodiment, in the condition receiving step S4 in the present embodiment, in addition to the conditions received in the condition receiving step S4 in the first embodiment, the condition receiving unit 64 receives, as conditions, a temperature outside the casing 30, a thrust force applied to the stationary component, a linear expansion coefficient of the bolt 39 according to temperature, and linear expansion coefficients and heat transfer coefficients of the upper-half casing 30U and the lower-half casing 30L according to temperature when the steam turbine 10 is in operation. Further, the condition receiving unit 64 receives, as the conditions, a change time from start to end of a change in the flow rate of the steam flowing into the casing 30, pressure distributions and temperature distributions in the casing 30 before and after the change in the flow rate of the steam, and a thrust force applied to the stationary component before and after the change in the flow rate of the steam when the steam turbine 10 is in operation.

In the pressure distribution estimating step S6 in the present embodiment, the pressure distribution estimating unit 66 simulates, by using the conditions received in the condition receiving step S4, the distribution of pressure applied to the flange surface when the casing 30 is in the fastened state and the steam turbine 10 is in operation, and after the change in the flow rate of the steam.

Also in the leakage evaluating step S7 in the present embodiment, the leakage evaluating unit 67 obtains the high leakage region 89 in which steam is highly likely to leak in the flange surface.

In the present embodiment, the pressure distribution of the flange surface when the casing 30 is in the fastened state and the steam turbine 10 is in operation and after the change in the flow rate of the steam is estimated by simulation. Accordingly, in the present embodiment, the sealing performance when the steam turbine 10 is in operation and after the change in the flow rate of the steam can be checked. Therefore, the present embodiment is effective for checking the sealing performance at the time of startup of the steam turbine 10 and for checking the sealing performance when the flow rate of the steam flowing into the steam turbine 10 rapidly changes.

### Fourth Embodiment of Method for Estimating a Flange Surface Pressure Distribution in a Rotary Machine and Method for Evaluating Leakage of a Fluid From Between Flange Surfaces

In the first embodiment, the distribution of pressure applied to the flange surface and the high leakage region 89 when the casing 30 is in the fastened state are estimated. On the other hand, the present embodiment estimates the pressure distribution of the flange surface when the casing 30 is in the fastened state and after creep deformation at a scheduled time point at which the casing 30 is brought into the open state after the steam turbine 10 is operated sometime following a current time point.

A device for executing the method according to the present embodiment is essentially the same as the device 50 described with reference to FIG. 6. However, as illustrated in FIG. 6, the device further includes a creep model receiving unit 62 as a functional unit. In addition, a procedure for executing the method is essentially the same as the execution procedure described in the flowchart illustrated in FIG. 7. However, as illustrated in the flowchart of FIG. 7, in the procedure for executing the method, a creep model receiving step S2 is executed after the reference model receiving step SI and before the measured coordinate receiving step S3. In addition, in the present embodiment, conditions received in the condition receiving step S4 are different from the conditions received in the condition receiving step S4 in the first embodiment.

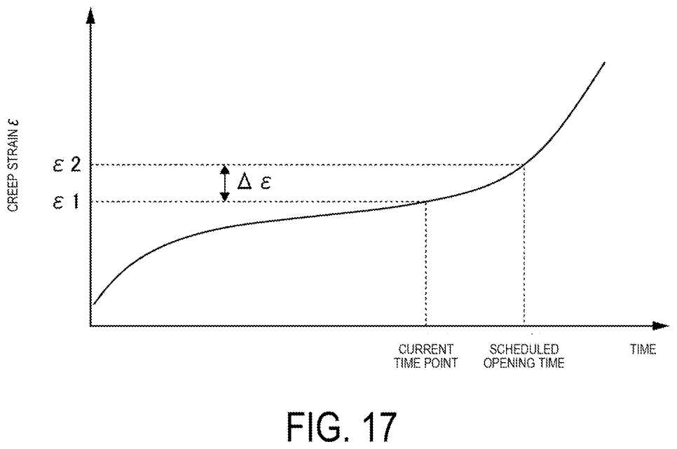

In the creep model receiving step S2 in the present embodiment, the creep model receiving unit 62 receives a creep model. As illustrated in FIG. 17, the creep model is a model showing a creep strain ε over rated operation time with respect to the upper-half casing 30U and the lower-half casing 30L.

Similar to the condition receiving step S4 in the second embodiment, in the condition receiving step S4 in the present embodiment, in addition to the conditions received in the condition receiving step S4 in the first embodiment, the condition receiving unit 64 receives, as conditions, a pressure distribution and a temperature distribution in the casing 30, a temperature outside the casing 30, a thrust force applied to the stationary component, a linear expansion coefficient of the bolt 39 according to temperature, and linear expansion coefficients and heat transfer coefficients of the upper-half casing 30U and the lower-half casing 30L according to temperature when the steam turbine 10 is in operation. Further, the condition receiving unit 64 receives, as the conditions, an accumulated operation time of the steam turbine 10 until a current time point and an accumulated operation time of the steam turbine 10 until the casing 30 is brought into the open state after the steam turbine 10 is operated sometime following the current time point.

In the pressure distribution estimating step S6 in the present embodiment, the pressure distribution estimating unit 66 simulates the pressure distribution of the flange surface after creep deformation at a scheduled time point at which the casing 30 is brought into the open state after the steam turbine 10 is operated sometime following a current time point by using the conditions received in the condition receiving step S4.

Creep deformation until a current time point has been reflected in measured three-dimensional coordinate data received in the measured coordinate receiving step S3. Thus, as illustrated in FIG. 17, the pressure distribution of the flange surface after creep deformation at a scheduled opening time point at which the casing 30 is brought into the open state after the steam turbine 10 is operated sometime following a current time point is simulated by using a difference Δε between a creep strain ε2 according to an accumulated operation time of the steam turbine 10 until the scheduled opening time point and a creep strain ε1 according to an accumulated operation time of the steam turbine 10 until the current time point.

Also in the leakage evaluating step S7 in the present embodiment, the leakage evaluating unit 67 obtains the high leakage region 89 in which steam is highly likely to leak in the flange surface.

The present embodiment estimates the pressure distribution of the flange surface after creep deformation at a scheduled time point at which the casing 30 is brought into the open state after the steam turbine 10 is operated sometime following a current time point. Accordingly, in the present embodiment, it is possible to check the sealing performance in consideration of creep deformation when the steam turbine 10 is operated after the current time point.

Note that the creep model receiving step S2 may be executed at any stage before the modified model creating step S5.

As above, the embodiments of the present disclosure have been described in detail. However, the present disclosure is not limited by the embodiments described above. Various additions, changes, substitutions, partial deletions, and the like can be made without departing from the scope and the spirit of the present invention derived from the contents and equivalents thereof defined in the claims.

### Supplementary Notes

The methods for estimating a flange surface pressure distribution in a rotary machine according to the embodiments described above can be understood, for example, as follows.
(1) A method for estimating a flange surface pressure distribution according to a first aspect is applied to a rotary machine below.

The rotary machine includes: a rotor 15 rotatable around an axis Ar extending in a horizontal direction; a casing 30 in which a working fluid can flow and which covers an outer periphery of the rotor 15; and a stationary component disposed in the casing 30 and attached to the casing 30. The casing 30 includes an upper-half casing 30U on an upper side, a lower-half casing 30L on a lower side, and a plurality of bolts 39 fastening the upper-half casing 30U to the lower-half casing 30L. The upper-half casing 30U includes an upper flange 32U formed with an upper flange surface 33U facing downward. The lower-half casing 30L includes a lower flange 32L formed with a lower flange surface 33L facing upward and opposing the upper flange surface 33U in the vertical direction Dz. The upper flange 32U and the lower flange 32L include bolt holes 34 penetrating therethrough in the vertical direction Dz, and the respective plurality of bolts 39 can be inserted into the bolt holes 34.

The method for estimating a flange surface pressure distribution in the above rotary machine includes:
a reference model receiving step SI of receiving a three-dimensional reference shape model 80 of the rotary machine, the three-dimensional reference shape model 80 having been acquired in advance;
a measured coordinate receiving step S3 of receiving measured three-dimensional coordinate data at a plurality of positions on the upper flange surface 33U and measured three-dimensional coordinate data at a plurality of positions on the lower flange surface 33L, the measured three-dimensional coordinate data being measured in an open state where the upper-half casing 30U is not fastened to the lower-half casing 30L by the plurality of bolts 39 after the rotary machine is disassembled;
a condition receiving step S4 of receiving conditions including a tightening torque of the plurality of bolts 39, an elastic coefficient of the plurality of bolts 39, elastic coefficients of the upper-half casing 30U and the lower-half casing 30L, weights of the upper-half casing 30U and the lower-half casing 30L, and a weight of the stationary component;
a modified model creating step S5 of creating a three-dimensional modified shape model 80m by modifying the three-dimensional reference shape model 80 based on the measured coordinate data at the plurality of positions received in the measured coordinate receiving step S3; and
a pressure distribution estimating step S6 of obtaining, by using the three-dimensional modified shape model 80m and under the conditions received in the condition receiving step S4, a pressure distribution of one flange surface out of the lower flange surface 33L and the upper flange surface 33U when a state changes to a fastened state where the upper-half casing 30U is fastened to the lower-half casing 30L by the plurality of bolts 39.

Conventionally, when the sealing performance between the upper flange 32U and the lower flange 32L is checked, a paint is first applied to one of check targets, and then the upper flange 32U is fastened to the lower flange 32L with bolts 39. Subsequently, the bolts 39 are removed, the upper-half casing 30U and the lower-half casing 30L are returned to the open state, and then the paint adhesion state of the remaining one of the check targets is checked. However, in the present aspect, the pressure distribution of one flange surface out of the upper flange surface 33U and the lower flange surface 33L when the casing 30 is brought into the fastened state is estimated. Accordingly, in the present aspect, in order to check the sealing performance between the upper flange 32U and the lower flange 32L, it is not necessary to bring the casing 30 in the open state into the fastened state and then return the casing 30 to the open state again, and thus it is possible to reduce the time and effort for checking the sealing performance.
(2) A method for estimating a flange surface pressure distribution according to a second aspect is the method for estimating a flange surface pressure distribution according to the first aspect, wherein in the condition receiving step S4, a pressure distribution and a temperature distribution in the casing 30, a temperature outside the casing 30, a thrust force applied to the stationary component, a linear expansion coefficient of the bolts 39 according to temperature, and linear expansion coefficients and heat transfer coefficients of the upper-half casing 30U and the lower-half casing 30L according to temperature when the rotary machine is in operation are received as the conditions. In the pressure distribution estimating step S6, a pressure distribution of the one flange surface when the casing 30 is in the fastened state and the rotary machine is in operation is obtained by using the conditions received in the condition receiving step S4.

In the present aspect, the pressure distribution of the one flange surface when the casing 30 is in the fastened state and the rotary machine is in operation is estimated. Accordingly, in the present aspect, the sealing performance when the rotary machine is in operation can be checked.
(3) A method for estimating a flange surface pressure distribution according to a third aspect is the method for estimating a flange surface pressure distribution according to the second aspect, wherein in the condition receiving step S4, a change time from start to end of a change in a flow rate of the working fluid flowing into the casing 30, pressure distributions and temperature distributions in the casing 30 before and after the change in the flow rate of the working fluid, and thrust forces applied to the stationary component before and after the change in the flow rate of the working fluid when the rotary machine is in operation are received as the conditions. In the pressure distribution estimating step S6, the pressure distribution of the one flange surface after the change in the flow rate of the working fluid flowing into the casing 30 when the rotary machine is in operation is obtained by using the conditions received in the condition receiving step S4.

In the present aspect, the pressure distribution of the one flange surface after the change in the flow rate of the working fluid when the casing 30 is in the fastened state and the rotary machine is in operation is estimated. Accordingly, in the present aspect, the sealing performance after the change in the flow rate of the working fluid when the rotary machine is in operation can be checked. Therefore, the present aspect is effective for checking the sealing performance at the time of startup of the rotary machine and for checking the sealing performance when the flow rate of the working fluid flowing into the rotary machine rapidly changes.
(4) A method for estimating a flange surface pressure distribution according to a fourth aspect is the method for estimating a flange surface pressure distribution according to the second aspect, wherein a creep model receiving step S2 of receiving a creep model showing a creep strain over time with respect to the upper-half casing 30U and the lower-half casing 30L is performed. In the condition receiving step S4, an accumulated operation time of the rotary machine until a current time point and an accumulated operation time of the rotary machine until the casing 30 is brought into the open state after the rotary machine is operated sometime following the current time point are received as the conditions. In the pressure distribution estimating step S6, the pressure distribution of the one flange surface after creep deformation at a scheduled time point at which the casing 30 is brought into the open state after the rotary machine is operated sometime following the current time point is obtained by using the conditions received in the condition receiving step S4.

The present aspect estimates the pressure distribution of the one flange surface after creep deformation at the scheduled time point at which the casing 30 is brought into the open state after the rotary machine is operated sometime following the current time point. Accordingly, in the present aspect, it is possible to check the sealing performance in consideration of creep deformation when the rotary machine is operated after the current time point.

The methods for evaluating leakage in a rotary machine according to the embodiments described above can be understood, for example, as follows.
(5) A method for evaluating leakage according to a fifth aspect includes:
the method for estimating a flange surface pressure distribution according to any one of the first aspect to the fourth aspect; and
a leakage evaluating step S7 of obtaining a region in which a value obtained by dividing a pressure indicated by the pressure distribution obtained in the pressure distribution estimating step S6 by a maximum pressure or a rated pressure of the working fluid is less than a predetermined tolerance.

In the present aspect, it is possible to easily check a region in the flange surface where the working fluid is highly likely to leak from between the upper flange surface 33U and the lower flange surface 33L. Accordingly, in the present aspect, the sealing performance can be checked more easily.

The programs for estimating a flange surface pressure distribution in a rotary machine according to the embodiments described above can be understood, for example, as follows.
(6) A program for estimating a flange surface pressure distribution according to a sixth aspect is applied to a rotary machine below.

The rotary machine includes: a rotor 15 rotatable around an axis Ar extending in a horizontal direction; a casing 30 in which a working fluid can flow and which covers an outer periphery of the rotor 15; and a stationary component disposed in the casing 30 and attached to the casing 30. The casing 30 includes an upper-half casing 30U on an upper side, a lower-half casing 30L on a lower side, and a plurality of bolts 39 fastening the upper-half casing 30U to the lower-half casing 30L. The upper-half casing 30U includes an upper flange 32U formed with an upper flange surface 33U facing downward. The lower-half casing 30L includes a lower flange 32L formed with a lower flange surface 33L facing upward and opposing the upper flange surface 33U in the vertical direction Dz. The upper flange 32U and the lower flange 32L include bolt holes 34 penetrating therethrough in the vertical direction Dz, and the respective plurality of bolts 39 can be inserted into the bolt holes 34.

The program for estimating a flange surface pressure distribution in the above rotary machine causes a computer to execute:
a reference model receiving step SI of receiving a three-dimensional reference shape model 80 of the rotary machine, the three-dimensional reference shape model 80 having been acquired in advance;
a measured coordinate receiving step S3 of receiving measured three-dimensional coordinate data at a plurality of positions on the upper flange surface 33U and measured three-dimensional coordinate data at a plurality of positions on the lower flange surface 33L, the measured three-dimensional coordinate data being measured in an open state where the upper-half casing 30U is not fastened to the lower-half casing 30L by the plurality of bolts 39 after the rotary machine is disassembled;
a condition receiving step S4 of receiving conditions including a tightening torque of the plurality of bolts 39, an elastic coefficient of the plurality of bolts 39, elastic coefficients of the upper-half casing 30U and the lower-half casing 30L, weights of the upper-half casing 30U and the lower-half casing 30L, and a weight of the stationary component;
a modified model creating step S5 of creating a three-dimensional modified shape model 80m by modifying the three-dimensional reference shape model 80 based on the measured coordinate data at the plurality of positions received in the measured coordinate receiving step S3; and
a pressure distribution estimating step S6 of obtaining, by using the three-dimensional modified shape model 80m and under the conditions received in the condition receiving step S4, a pressure distribution of one flange surface out of the lower flange surface 33L and the upper flange surface 33U when a state changes to a fastened state where the upper-half casing 30U is fastened to the lower-half casing 30L by the plurality of bolts 39.

By causing the computer to execute the program according to the present aspect, the time and effort for checking the sealing performance between the upper flange surface 33U and the lower flange surface 33L can be reduced as in the method according to the first aspect.
(7) A program for estimating a flange surface pressure distribution according to a seventh aspect is the program for estimating a flange surface pressure distribution according to the sixth aspect, wherein in the condition receiving step S4, a pressure distribution and a temperature distribution in the casing 30, a temperature outside the casing 30, a thrust force applied to the stationary component, a linear expansion coefficient of the bolts 39 according to temperature, and linear expansion coefficients and heat transfer coefficients of the upper-half casing 30U and the lower-half casing 30L according to temperature when the rotary machine is in operation are received as the conditions. In the pressure distribution estimating step S6, a pressure distribution of the one flange surface when the casing 30 is in the fastened state and the rotary machine is in operation is obtained by using the conditions received in the condition receiving step S4.

By causing the computer to execute the program according to the present aspect, the sealing performance when the rotary machine is in operation can be checked as in the method according to the second aspect.
(8) A program for estimating a flange surface pressure distribution according to an eighth aspect is the program for estimating a flange surface pressure distribution according to the seventh aspect, wherein in the condition receiving step S4, a change time from start to end of a change in a flow rate of the working fluid flowing into the casing 30, pressure distributions and temperature distributions in the casing 30 before and after the change in the flow rate of the working fluid, and thrust forces applied to the stationary component before and after the change in the flow rate of the working fluid when the rotary machine is in operation are received as the conditions. In the pressure distribution estimating step S6, the pressure distribution of the one flange surface after the change in the flow rate of the working fluid flowing into the casing 30 when the rotary machine is in operation is obtained by using the conditions received in the condition receiving step S4.

By causing the computer to execute the program according to the present aspect, the sealing performance when the rotary machine is in operation and after the change in the flow rate of the working fluid can be checked as in the method according to the third aspect.
(9) A program for estimating a flange surface pressure distribution according to a ninth aspect is the program for estimating a flange surface pressure distribution according to the seventh aspect, wherein the computer is caused to execute a creep model receiving step S2 of receiving a creep model showing a creep strain over time with respect to the upper-half casing 30U and the lower-half casing 30L. In the condition receiving step S4, an accumulated operation time of the rotary machine until a current time point and an accumulated operation time of the rotary machine until the casing 30 is brought into the open state after the rotary machine is operated sometime following the current time point are received as the conditions. In the pressure distribution estimating step S6, the pressure distribution of the one flange surface after creep deformation at a scheduled time point at which the casing 30 is brought into the open state after the rotary machine is operated sometime following the current time point is obtained by using the conditions received in the condition receiving step S4.

By causing the computer to execute the program according to the present aspect, it is possible to check the sealing performance in consideration of creep deformation when the rotary machine is operated after the current time point as in the method according to the fourth aspect.

The program for evaluating leakage in a rotary machine according to the embodiments described above can be understood, for example, as follows.
(10) A program for evaluating leakage according to a tenth aspect includes the program for estimating flange surface pressure distribution according to any one of the sixth aspect to the ninth aspect, and causes the computer to execute a leakage evaluating step S7 of obtaining a region in which a value obtained by dividing a pressure indicated by the pressure distribution obtained in the pressure distribution estimating step S6 by a maximum pressure or a rated pressure of the working fluid is less than a predetermined tolerance.

By causing the computer to execute the program according to the present aspect, it is possible to easily check a region in the flange surface where the working fluid is highly likely to leak from between the upper flange surface 33U and the lower flange surface 33L as in the method according to the fifth aspect.

The devices for estimating a flange surface pressure distribution in a rotary machine according to the embodiments described above can be understood, for example, as follows.
(11) A device for estimating a flange surface pressure distribution according to an eleventh aspect is applied to a rotary machine below.

The rotary machine includes: a rotor 15 rotatable around an axis Ar extending in a horizontal direction; a casing 30 in which a working fluid can flow and which covers an outer periphery of the rotor 15; and a stationary component disposed in the casing 30 and attached to the casing 30. The casing 30 includes an upper-half casing 30U on an upper side, a lower-half casing 30L on a lower side, and a plurality of bolts 39 fastening the upper-half casing 30U to the lower-half casing 30L. The upper-half casing 30U includes an upper flange 32U formed with an upper flange surface 33U facing downward. The lower-half casing 30L includes a lower flange 32L formed with a lower flange surface 33L facing upward and opposing the upper flange surface 33U in the vertical direction Dz. The upper flange 32U and the lower flange 32L include bolt holes 34 penetrating therethrough in the vertical direction Dz, and the respective plurality of bolts 39 can be inserted into the bolt holes 34.

A device for estimating a flange surface pressure distribution 50a in the above rotary machine includes:
a reference model receiving unit 61 configured to receive a three-dimensional reference shape model 80 of the rotary machine, the three-dimensional reference shape model 80 having been acquired in advance;
a measured coordinate receiving unit 63 configured to receive measured three-dimensional coordinate data at a plurality of positions on the upper flange surface 33U and measured three-dimensional coordinate data at a plurality of positions on the lower flange surface 33L, the measured three-dimensional coordinate data being measured in an open state where the upper-half casing 30U is not fastened to the lower-half casing 30L by the plurality of bolts 39 after the rotary machine is disassembled;
a condition receiving unit 64 configured to receive conditions including a tightening torque of the plurality of bolts 39, an elastic coefficient of the plurality of bolts 39, elastic coefficients of the upper-half casing 30U and the lower-half casing 30L, weights of the upper-half casing 30U and the lower-half casing 30L, and a weight of the stationary component;
a modified model creating unit 65 configured to create a three-dimensional modified shape model 80m by modifying the three-dimensional reference shape model 80 based on the measured coordinate data at the plurality of positions received by the measured coordinate receiving unit 63; and
a pressure distribution estimating unit 66 configured to obtain, by using the three-dimensional modified shape model 80m and under the conditions received by the condition receiving unit 64, a pressure distribution of one flange surface out of the lower flange surface 33L and the upper flange surface 33U when a state changes to a fastened state where the upper-half casing 30U is fastened to the lower-half casing 30L by the plurality of bolts 39.

Similar to the method according to the first aspect, in the present aspect, the time and effort for checking the sealing performance between the upper flange surface 33U and the lower flange surface 33L can be reduced.
(12) A device for estimating a flange surface pressure distribution according to a twelfth aspect is the device for estimating a flange surface pressure distribution 50a according to the eleventh aspect, wherein the condition receiving unit 64 receives, as the conditions, a pressure distribution and a temperature distribution in the casing 30, a temperature outside the casing 30, a thrust force applied to the stationary component, a linear expansion coefficient of the bolts 39 according to temperature, and linear expansion coefficients and heat transfer coefficients of the upper-half casing 30U and the lower-half casing 30L according to temperature when the rotary machine is in operation. The pressure distribution estimating unit 66 obtains a pressure distribution of the one flange surface when the casing 30 is in the fastened state and the rotary machine is in operation by using the conditions received by the condition receiving unit 64.

Similar to the method according to the second aspect, in the present aspect, the sealing performance when the rotary machine is in operation can be checked.
(13) A device for estimating a flange surface pressure distribution according to a thirteenth aspect is the device for estimating a flange surface pressure distribution 50a according to the twelfth aspect, wherein the condition receiving unit 64 receives, as the conditions, a change time from start to end of a change in a flow rate of the working fluid flowing into the casing 30, pressure distributions and temperature distributions in the casing 30 before and after the change in the flow rate of the working fluid, and thrust forces applied to the stationary component before and after the change in the flow rate of the working fluid when the rotary machine is in operation. The pressure distribution estimating unit 66 obtains the pressure distribution of the one flange surface after the change in the flow rate of the working fluid flowing into the casing 30 when the rotary machine is in operation by using the conditions received by the condition receiving unit 64.

Similar to the method according to the third aspect, in the present aspect, the sealing performance when the rotary machine is in operation and after the change in the flow rate of the working fluid can be checked.
(14) A device for estimating a flange surface pressure distribution according to a fourteenth aspect is the device for estimating a flange surface pressure distribution 50a according to the twelfth aspect further including a creep model receiving unit 62 configured to receive a creep model that shows a creep strain over time with respect to the upper-half casing 30U and the lower-half casing 30L. The condition receiving unit 64 receives, as the conditions, an accumulated operation time of the rotary machine until a current time point and an accumulated operation time of the rotary machine until the casing 30 is brought into the open state after the rotary machine is operated sometime following the current time point. The pressure distribution estimating unit 66 obtains the pressure distribution of the one flange surface after creep deformation at a scheduled time point at which the casing 30 is brought into the open state after the rotary machine is operated sometime following the current time point by using the conditions received by the condition receiving unit 64.

By causing the computer to execute the program according to the present aspect, it is possible to check the sealing performance in consideration of creep deformation when the rotary machine is operated after the current time point as in the method according to the fourth aspect.

The device for evaluating leakage in a rotary machine according to the embodiments described above can be understood, for example, as follows.
(15) A device for evaluating leakage according to a fifteenth aspect includes:
the device for estimating a flange surface pressure distribution 50a according to any one of the eleventh aspect to the fourteenth aspect; and
a leakage evaluating unit 67 configured to obtain a region in which a value obtained by dividing a pressure indicated by the pressure distribution obtained by the pressure distribution estimating unit 66 by a maximum pressure or a rated pressure of the working fluid is less than a predetermined tolerance.

Similar to the method according to the fifth aspect, in the present aspect, it is possible to easily check a region in the flange surface where the working fluid is highly likely to leak from between the upper flange surface 33U and the lower flange surface 33L.

### INDUSTRIAL APPLICABILITY

According to one aspect of the present disclosure, a flange surface pressure distribution in a rotary machine can be estimated, and thus the time and effort for checking the sealing performance between the two flanges can be reduced.

### REFERENCE SIGNS LIST

10: Steam turbine (rotary machine)
11: Frame
12a: First shaft bearing device
12b: Second shaft bearing device
13a: First shaft sealing device (stationary component)
13b: Second shaft sealing device (stationary component)
15: Rotor
16: Rotor shaft
17: Rotor blade row
20: Diaphragm (stationary component)
20L: Lower-half diaphragm
20U: Upper-half diaphragm
22: Stator vane
23: Diaphragm inner ring
24: Diaphragm outer ring
25: Sealing device
30: Casing
30L: Lower-half casing
30U: Upper-half casing
31L: Lower-half casing main body
31U: Upper-half casing main body
32L: Lower flange
32U: Upper flange
33L: Lower flange surface
33U: Upper flange surface
34: Bolt hole
35a: First supported portion
35ap: Upper surface
35b: Second supported portion
35bp: Upper surface
36: Stationary component storage portion
39: Bolt
50: Device for evaluating leakage
50a: Device for estimating a flange surface pressure distribution
51: Manual input device
52: Display device
53: Input/output interface
54: Device interface
55: Communication interface
56: Storage and reproduction device
57: Memory
58: Auxiliary storage device
58d: Reference three-dimensional shape data
58p: Program for evaluating leakage
58pa: Program for estimating a flange surface pressure distribution
60: CPU
61: Reference model receiving unit
62: Creep model receiving unit
63: Measured coordinate receiving unit
64: Condition receiving unit
65: Modified model creating unit
66: Pressure distribution estimating unit
67: Leakage evaluating unit
69: Three-dimensional shape measuring device
80: Three-dimensional reference shape model
80m: Three-dimensional modified shape model
81: Flange surface
82: Surface inclined with respect to a flange surface
83: Three-dimensional block
85: Point
86, 86a, 86b: Polygon (polygon plane)
87: Representative point
89: High leakage region
Ar: Axis
Dc: Circumferential direction
Dr: Radial direction
Dri: Radial inner side
Dro: Radial outer side
Dx: Lateral direction
Dy: Axial direction
Dz: Vertical direction

1. A method for estimating a flange surface pressure distribution in a rotary machine,
the rotary machine comprising:
a rotor rotatable about an axis extending in a horizontal direction;
a casing in which a working fluid flows, the casing being configured to cover an outer periphery of the rotor; and
a stationary component disposed in the casing and attached to the casing,
the casing including an upper-half casing on an upper side, a lower-half casing on a lower side, and a plurality of bolts configured to fasten the upper-half casing to the lower-half casing,
the upper-half casing including an upper flange formed with an upper flange surface facing downward,
the lower-half casing including a lower flange formed with a lower flange surface facing upward and opposing the upper flange surface in a vertical direction,
the upper flange and the lower flange including bolt holes which extend through the upper flange and the lower flange in the vertical direction, and into which each of the plurality of bolts is insertable,
the method comprising:
a reference model receiving step of receiving a three-dimensional reference shape model of the rotary machine, the three-dimensional reference shape model being acquired in advance;
a measured coordinate receiving step of receiving measured three-dimensional coordinate data at a plurality of positions on the upper flange surface and measured three-dimensional coordinate data at a plurality of positions on the lower flange surface, the measured three-dimensional coordinate data being measured in an open state where the upper-half casing is not fastened to the lower-half casing by the plurality of bolts after the rotary machine is disassembled;
a condition receiving step of receiving conditions including a tightening torque of the plurality of bolts, an elastic coefficient of the plurality of bolts, elastic coefficients of the upper-half casing and the lower-half casing, weights of the upper-half casing and the lower-half casing, and a weight of the stationary component;
a modified model creating step of creating a three-dimensional modified shape model by modifying the three-dimensional reference shape model based on the measured three-dimensional coordinate data at the plurality of positions received in the measured coordinate receiving step; and
a pressure distribution estimating step of obtaining, by using the three-dimensional modified shape model and under the conditions received in the condition receiving step, a pressure distribution of one flange surface out of the lower flange surface and the upper flange surface in a fastened state where the upper-half casing is fastened to the lower-half casing by the plurality of bolts.

2. The method for estimating a flange surface pressure distribution according to claim 1, wherein
the condition receiving step includes receiving, as the conditions, a pressure distribution and a temperature distribution in the casing, a temperature outside the casing, a thrust force applied to the stationary component, a linear expansion coefficient of the bolts according to temperature, and linear expansion coefficients according to temperature and heat transfer coefficients according to temperature of the upper-half casing and the lower-half casing, when the rotary machine is in operation, and
the pressure distribution estimating step includes obtaining a pressure distribution of the one flange surface when the casing is in the fastened state and the rotary machine is in operation, by using the conditions received in the condition receiving step.

3. The method for estimating a flange surface pressure distribution according to claim 2, wherein
the condition receiving step includes receiving, as the conditions, a change time from start to end of a change in a flow rate of the working fluid flowing into the casing, pressure distributions and temperature distributions in the casing before and after the change in the flow rate of the working fluid, and thrust forces applied to the stationary component before and after the change in the flow rate of the working fluid, when the rotary machine is in operation, and
the pressure distribution estimating step includes obtaining a pressure distribution of the one flange surface when the rotary machine is in operation and after the change in the flow rate of the working fluid flowing into the casing, by using the conditions received in the condition receiving step.

4. The method for estimating a flange surface pressure distribution according to claim 2, further comprising
a creep model receiving step of receiving a creep model indicating a creep strain over time with respect to the upper-half casing and the lower-half casing,
wherein
the condition receiving step includes receiving, as the conditions, an accumulated operation time of the rotary machine until a current time point and an accumulated operation time of the rotary machine until the casing is brought into the open state after the rotary machine is operated after the current time point, and
the pressure distribution estimating step includes obtaining a pressure distribution of the one flange surface after creep deformation at a scheduled time point at which the casing is brought into the open state after the rotary machine is operated after the current time point, by using the conditions received in the condition receiving step.

5. A method for evaluating leakage, the method comprising:
the method for estimating a flange surface pressure distribution described in claim 1; and
a leakage evaluating step of obtaining a region in which a value obtained by dividing a pressure indicated by a pressure distribution obtained in a pressure distribution estimating step by a maximum pressure or a rated pressure of the working fluid is less than a predetermined tolerance.

6. A non-transitory computer-readable storage medium storing a computer program for estimating a flange surface pressure distribution in a rotary machine,
the rotary machine comprising:
a rotor rotatable about an axis extending in a horizontal direction;
a casing in which a working fluid flow, the casing being configured to cover an outer periphery of the rotor; and
a stationary component disposed in the casing and attached to the casing,
the casing including an upper-half casing on an upper side, a lower-half casing on a lower side, and a plurality of bolts configured to fasten the upper-half casing to the lower-half casing,
the upper-half casing including an upper flange formed with an upper flange surface facing downward,
the lower-half casing including a lower flange formed with a lower flange surface facing upward and opposing the upper flange surface in a vertical direction, and
the upper flange and the lower flange including bolt holes which extend through the upper flange and the lower flange in the vertical direction, and into which each of the plurality of bolts being insertable,
the program causing a computer to execute:
a reference model receiving step of receiving a three-dimensional reference shape model of the rotary machine, the three-dimensional reference shape model being acquired in advance;
a measured coordinate receiving step of receiving measured three-dimensional coordinate data at a plurality of positions on the upper flange surface and measured three-dimensional coordinate data at a plurality of positions on the lower flange surface, the measured three-dimensional coordinate data being measured in an open state where the upper-half casing is not fastened to the lower-half casing by the plurality of bolts after the rotary machine is disassembled;
a condition receiving step of receiving conditions including a tightening torque of the plurality of bolts, an elastic coefficient of the plurality of bolts, elastic coefficients of the upper-half casing and the lower-half casing, weights of the upper-half casing and the lower-half casing, and a weight of the stationary component;
a modified model creating step of creating a three-dimensional modified shape model by modifying the three-dimensional reference shape model based on the measured three-dimensional coordinate data at the plurality of positions received in the measured coordinate receiving step; and
a pressure distribution estimating step of obtaining, by using the three-dimensional modified shape model and under the conditions received in the condition receiving step, a pressure distribution of one flange surface out of the lower flange surface and the upper flange surface in a fastened state where the upper-half casing is fastened to the lower-half casing by the plurality of bolts.

7. The non-transitory computer-readable storage medium storing the computer program for estimating a flange surface pressure distribution according to claim 6, wherein
the condition receiving step includes receiving, as the conditions, a pressure distribution and a temperature distribution in the casing, a temperature outside the casing, a thrust force applied to the stationary component, a linear expansion coefficient of the bolts according to temperature, and linear expansion coefficients according to temperature and heat transfer coefficients according to temperature of the upper-half casing and the lower-half casing when the rotary machine is in operation, and
the pressure distribution estimating step includes obtaining a pressure distribution of the one flange surface when the casing is in the fastened state and the rotary machine is in operation, by using the conditions received in the condition receiving step.

8. The non-transitory computer-readable storage medium storing the computer program for estimating a flange surface pressure distribution according to claim 7, wherein
the condition receiving step includes receiving, as the conditions, a change time from start to end of a change in a flow rate of the working fluid flowing into the casing, pressure distributions and temperature distributions in the casing before and after the change in the flow rate of the working fluid, and thrust forces applied to the stationary component before and after the change in the flow rate of the working fluid, when the rotary machine is in operation, and
the pressure distribution estimating step includes obtaining a pressure distribution of the one flange surface when the rotary machine is in operation and after the change in the flow rate of the working fluid flowing into the casing, by using the conditions received in the condition receiving step.

9. The non-transitory computer-readable storage medium storing the computer program for estimating a flange surface pressure distribution according to claim 7, the program further causing the computer to execute a creep model receiving step of receiving a creep model indicating a creep strain over time with respect to the upper-half casing and the lower-half casing,
wherein
the condition receiving step includes receiving, as the conditions, an accumulated operation time of the rotary machine until a current time point and an accumulated operation time of the rotary machine until the casing is brought into the open state after the rotary machine is operated after the current time point, and
the pressure distribution estimating step includes obtaining a pressure distribution of the one flange surface after creep deformation at a scheduled time point at which the casing is brought into the open state after the rotary machine is operated after the current time point, by using the conditions received in the condition receiving step.

10. A non-transitory computer-readable storage medium storing a computer program for evaluating leakage,
the program
comprising the computer program for estimating a flange surface pressure distribution described in claim 6, and
causing the computer to execute a leakage evaluating step of obtaining a region in which a value obtained by dividing a pressure indicated by the pressure distribution obtained in the pressure distribution estimating step by a maximum pressure or a rated pressure of the working fluid is less than a predetermined tolerance.

11. A device for estimating a flange surface pressure distribution in a rotary machine,
the rotary machine comprising:
a rotor rotatable about an axis extending in a horizontal direction;
a casing in which a working fluid flow, the casing being configured to cover an outer periphery of the rotor; and
a stationary component disposed in the casing and attached to the casing,
the casing including an upper-half casing on an upper side, a lower-half casing on a lower side, and a plurality of bolts configured to fasten the upper-half casing to the lower-half casing,
the upper-half casing including an upper flange formed with an upper flange surface facing downward,
the lower-half casing including a lower flange formed with a lower flange surface facing upward and opposing the upper flange surface in a vertical direction, and
the upper flange and the lower flange including bolt holes which extend through the upper flange and the lower flange in the vertical direction, and into which each of the plurality of bolts is insertable,
the device comprising:
a reference model receiving unit configured to receive a three-dimensional reference shape model of the rotary machine, the three-dimensional reference shape model being acquired in advance;
a measured coordinate receiving unit configured to receive measured three-dimensional coordinate data at a plurality of positions on the upper flange surface and measured three-dimensional coordinate data at a plurality of positions on the lower flange surface, the measured three-dimensional coordinate data being measured in an open state where the upper-half casing is not fastened to the lower-half casing by the plurality of bolts after the rotary machine is disassembled;
a condition receiving unit configured to receive conditions including a tightening torque of the plurality of bolts, an elastic coefficient of the plurality of bolts, elastic coefficients of the upper-half casing and the lower-half casing, weights of the upper-half casing and the lower-half casing, and a weight of the stationary component;
a modified model creating unit configured to create a three-dimensional modified shape model by modifying the three-dimensional reference shape model based on the measured three-dimensional coordinate data at the plurality of positions received by the measured coordinate receiving unit; and
a pressure distribution estimating unit configured to obtain, by using the three-dimensional modified shape model and under the conditions received by the condition receiving unit, a pressure distribution of one flange surface out of the lower flange surface and the upper flange surface in a fastened state where the upper-half casing is fastened to the lower-half casing by the plurality of bolts.

12. The device for estimating a flange surface pressure distribution according to claim 11, wherein
the condition receiving unit receives, as the conditions, a pressure distribution and a temperature distribution in the casing, a temperature outside the casing, a thrust force applied to the stationary component, a linear expansion coefficient of the bolts according to temperature, and linear expansion coefficients according to temperature and heat transfer coefficients according to temperature of the upper-half casing and the lower-half casing when the rotary machine is in operation, and
the pressure distribution estimating unit obtains a pressure distribution of the one flange surface when the casing is in the fastened state and the rotary machine is in operation by using the conditions received by the condition receiving unit.

13. The device for estimating a flange surface pressure distribution according to claim 12, wherein
the condition receiving unit receives, as the conditions, a change time from start to end of a change in a flow rate of the working fluid flowing into the casing, pressure distributions and temperature distributions in the casing before and after the change in the flow rate of the working fluid, and thrust forces applied to the stationary component before and after the change in the flow rate of the working fluid when the rotary machine is in operation, and
the pressure distribution estimating unit obtains a pressure distribution of the one flange surface when the rotary machine is in operation and after the change in the flow rate of the working fluid flowing into the casing, by using the conditions received by the condition receiving unit.

14. The device for estimating a flange surface pressure distribution according to claim 12, further comprising a creep model receiving unit configured to receive a creep model indicating a creep strain over time with respect to the upper-half casing and the lower-half casing,
wherein
the condition receiving unit receives, as the conditions, an accumulated operation time of the rotary machine until a current time point and an accumulated operation time of the rotary machine until the casing is brought into the open state after the rotary machine is operated after the current time point, and
the pressure distribution estimating unit obtains a pressure distribution of the one flange surface after creep deformation at a scheduled time point at which the casing is brought into the open state after the rotary machine is operated after the current time point by using the conditions received by the condition receiving unit.

15. A device for evaluating leakage, the device comprising:
the device for estimating a flange surface pressure distribution described in claim 11; and
a leakage evaluating unit configured to obtain a region in which a value obtained by dividing a pressure indicated by the pressure distribution obtained by the pressure distribution estimating unit by a maximum pressure or a rated pressure of the working fluid is less than a predetermined tolerance.
